(19) United States
(12) Patent Application Publication
(10) Pub. No.: US 2005/0110128 A1
(43) Pub. Date: May 26, 2005

(54) Highly reliable stack type semiconductor package

(76) Inventors: Eun-Chul Ahn, Chungcheongnam-do (KR); Tae-Sung Park, Chungcheongnam-do (KR)

Correspondence Address: MARGER JOHNSON & MCCOLLOM, P.C., 1030 SW MORRISON STREET, PORTLAND, OR, 97205, US

(21) Appl. No.: 10/993,693

(22) Filed: Nov. 19, 2004

(30) Foreign Application Priority Data
Nov. 26, 2003 (KR) 2003-84732

(51) Int. Cl. H01L 21/48; H01L 23/02

(52) U.S. Cl. 257/686; 438/109

(57) ABSTRACT

A highly reliable stack type semiconductor package, which does not have a problem of interconnection areas becoming disconnected due to thermal expansion. The semiconductor package includes a second die adhesive, which is formed between a first semiconductor chip and a second semiconductor chip, applied to the upper surface of the first semiconductor chip, and extends to the wire forming units. The second die adhesive is selected to have a bulk modulus greater than 1 GPa to prevent electric disconnection due to breakage of wires in the stack type semiconductor package during thermal stress.

This application claims the priority of Korean Patent Application No. 2003-84732, filed on Nov. 26, 2003, in the Korean Intellectual Property Office, the disclosure of which is incorporated herein by reference in its entirety.

### BACKGROUND OF THE INVENTION

1. Field of the Invention

The present invention relates to a semiconductor package, and more particularly, to a stack type semiconductor package in which a plurality of semiconductor chips are mounted.

2. Description of the Related Art

Semiconductor manufacturers have developed methods to increase integration and reduce the size of semiconductor devices. However, since research has to be carried out and investment in equipment must be made to increase integration of the semiconductor devices, the overall manufacturing cost of the semiconductor devices increases. For example, for manufacturing semiconductor memory devices, a large number of technical problems must be solved in the wafer manufacturing process and new equipment must be developed to increase from 64 MDRAM to 256 MDRAM.

The development of semiconductor packages has provided a method of increasing the integrity without requiring technical development and investment in equipment since a semiconductor package includes a plurality of semiconductor chips without increased integration. Manufacturing the semiconductor package by mounting a plurality of semiconductor chips requires less effort to increase integration than to increase integration during the wafer manufacturing process. For example, it is possible to manufacture a 256 MDRAM by assembling a semiconductor package that includes four 64 MDRAM semiconductor chips.

Initially, methods of manufacturing a semiconductor package included horizontally arranging the semiconductor chips so that the size of the semiconductor package was not reduced. However, most multi-chip type semiconductor packages are now manufactured by vertically arranging the semiconductor chips.

Micron Technology, Inc. developed a method of manufacturing a semiconductor package by vertically stacking single semiconductor chips, which is included in U.S. Pat. No. 6,569,709, entitled “Assemblies Including Stacked Semiconductor Devices Separated a Distance Defined by Adhesive Material Interposed Therebetween, Packages Including the Assembly, and Method”.

FIGS. 1 and 2 are sectional views of conventional stack type semiconductor packages.

Referring to FIG. 1, a sectional view of a ball grid array (BGA) package 10 using solder balls 14 as external connection terminals is shown. Here, first and second semiconductor chips 30a and 30b are vertically stacked on a substrate 20 using a conventional die adhesive 36. To manufacture the BGA package 10, the first semiconductor chip 30a is mounted on the substrate 20 using an adhesive tape 26, and bond pads 34 on the first semiconductor chip 30a are electrically connected by first wires 38a to bond fingers which are contact units 24 on the substrate 20. Thereafter, the conventional die adhesive 36 is sprayed, and the second semiconductor chip 30b is adhered to the conventional die adhesive 36. Then, the bond pads 34 on the second semiconductor chip 30b and the contact units 24 on the substrate are connected by second wires 38b. Finally, the resultant structure is sealed using an epoxy mold compound (EMC) as a sealing resin 40.

Conventionally, when the sizes of the first semiconductor chip 30a and the second semiconductor chip 30b are the same, the first semiconductor chip 30a and the second semiconductor chip 30b are adhered using the die adhesive 36, which has a bulk modulus less than 1 GPa. However, since the die adhesive 36 covers the interconnection areas of the first wires 38a on the first semiconductor chip 30a, the reliability of the BGA package 10 is lowered, as explained below.

Since the coefficients of thermal expansion of the die adhesive 36, the first wires 38a, and the first and second semiconductor chips 30a and 30b are different, the reliability is lowered when the temperature of electric equipment included in the BGA package 10 changes. Thus, the first wires 38a are broken at the bond pads on which the first wires 38a are connected to the first semiconductor chip 30a. When the first wires 38a break, electrical connections are broken, and the BGA package 10 cannot operate properly.

A temperature cycle test is a test for determining the reliability of a semiconductor package. In the test, the temperature of the semiconductor package fluctuates between a temperature of −55° C. and 125° C. during a time span of 30 minutes a predetermined number of times. As a result, the operation of the semiconductor package over a range of temperatures is determined.

In a study of 126 BGA packages with the die adhesive having a bulk modulus less than 1 GPa, when the 126 units of BGA packages were temperature cycle tested 150 times, none of the BGA packages failed, 2 units failed after 300 times of temperature cycle tests, 13 units of BGA packages failed after 600 times of temperature cycle tests, and 56 units of BGA packages failed after 1,000 times of temperature cycle test.

Semiconductor packages to be used in special situations, such as space engineering or military operations, should not fail, even when the temperature cycle test is performed more than 1,000 times. However, about 46% of the BGA packages using the conventional die adhesive failed after 1000 times. Accordingly, the BGA package using the conventional die adhesive cannot be used in situations in which the temperature has large fluctuations.

Referring to FIG. 2, in order to improve the reliability of the BGA package 10, the die adhesive 36 is not extended to the first wire interconnection areas, which is denoted by A in FIG. 2. Instead, the first wire interconnection areas are filled with the sealing resin 40, such as the EMC, which has excellent adhesive strength and hardness. However, in this case, it is difficult to precisely control the amount, the viscosity, and the expansion of the die adhesive 36 on the first semiconductor chip. Accordingly, additional processes are required, and it is difficult to manufacture the BGA package 10′. Furthermore, when the bond pads are formed at the center of the semiconductor chip, as illustrated in FIG. 3, it is difficult to apply the die adhesive while avoiding the first wire interconnection areas.

### SUMMARY OF THE INVENTION

The present invention provides a highly reliable stack type semiconductor package which prevents electric disconnection at wire interconnection areas.

According to an aspect of the present invention, there is provided a highly reliable stack type semiconductor package, comprising a basis frame of the semiconductor package, a first semiconductor chip mounted on the basis frame by using a first die adhesive, first wires, which connect bond pads on the first semiconductor chip to contact units on the basis frame, a second die adhesive having a bulk modulus greater than 1 GPa, which is formed on the first semiconductor chip having the first wires while being expanded to the edges of the first semiconductor chip, a second semiconductor chip attached to the first semiconductor chip by using the second die adhesive, second wires, which connect bond pads on the second semiconductor chip to the contact units on the basis frame, and a sealing portion, which seals the upper portion of the basis frame on which the second semiconductor chip and the second wires are formed.

The basis frame may be one selected from a lead frame and a printed circuit board, and the first semiconductor chip may be one selected from a semiconductor chip on which bond pads are formed at the center and a semiconductor chip on which bond pads are formed at the edges.

The type of the stack type semiconductor package may be one selected from a small outline package (SOP), a quad flat package (QFP), a ball grid array (BGA) package, and a chip scale package (CSP), and the stack type semiconductor package may further include a third semiconductor chip mounted on the second semiconductor chip while having the same structure as the second semiconductor chip. In addition, the stack type semiconductor package may further include a heat sink, which efficiently radiates heat to the outside.

According to another aspect of the present invention, there is provided a stack type semiconductor package having high reliability comprising a substrate used as a basis frame of the semiconductor package; a first semiconductor chip mounted on the substrate by using a first die adhesive; first wires, which connect bond pads on the first semiconductor chip to contact units on the substrate; a second die adhesive having the bulk modulus greater than 1 GPa, which covers first wire interconnection areas on the first semiconductor chip; a third die adhesive, which completely covers the surface of the first semiconductor chip on which the second die adhesive is coated, while having a height greater than the height of the first wires; a second semiconductor chip mounted on the first semiconductor chip by using the third die adhesive; second wires, which connect bond pads on the second semiconductor chip to contact units on the substrate; and a sealing resin, which completely seals the second wires and the second semiconductor chip on the substrate.

The size of the second semiconductor chip may be the same as or greater than that of the first semiconductor chip. In addition, the bulk modulus of the second die adhesive may be measured at a temperature of 0C.

Accordingly, the stack type semiconductor package has high reliability by using the die adhesive with a bulk modulus greater than 1 GPa, so that the first wires are prevented from being electrically disconnected, even during extreme temperature changes.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are sectional views of a conventional stack type semiconductor package;

FIG. 3 is a sectional view of a stack type semiconductor package according to a first embodiment of the present invention;

FIG. 4 is a sectional view of a stack type semiconductor package according to a second embodiment of the present invention;

FIG. 5A is a plan view of a semiconductor chip included in the stack type semiconductor package of FIG. 3;

FIG. 5B is a plan view of a semiconductor chip included in the stack type semiconductor package of FIG. 4;

FIG. 6 is a sectional view of a stack type semiconductor package according to a third embodiment of the present invention;

FIG. 7 is a sectional view of a stack type semiconductor package according to a fourth embodiment of the present invention;

FIG. 8 is a sectional view of a stack type semiconductor package according to a fifth embodiment of the present invention; and

FIG. 9 is a sectional view of a stack type semiconductor package according to a sixth embodiment of the present invention.

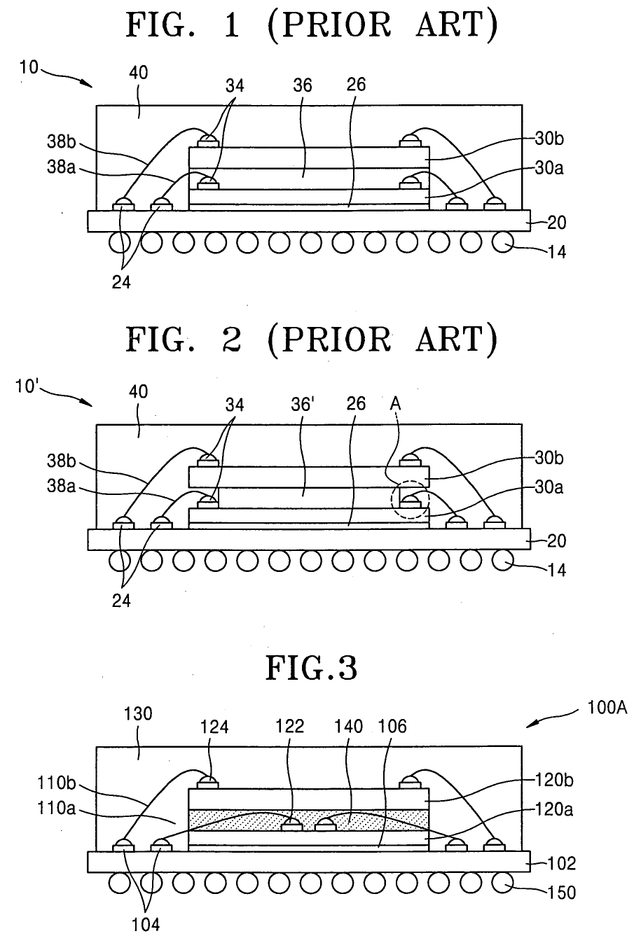

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

FIG. 3 is a sectional view of a stack type semiconductor package 100A according to a first embodiment of the present invention.

Referring to FIG. 3, a stack type semiconductor package 100A includes a basis frame 102, which is formed of a lead frame and a substrate, a first semiconductor chip 120a, first wires 110a, a second die adhesive 140, a second semiconductor chip 120b, second wires 110b, and a sealing portion 130. The first semiconductor chip 120a is mounted on the basis frame 102 using a first die adhesive 106. The first wires 110a connect bond pads 122, which are formed near the center of the first semiconductor chip 120a, with contact units 104 on the basis frame 102. The second die adhesive 140 is formed on the first semiconductor chip 120a on which the first wires 110a are formed, and the second die adhesive 140 is expanded to the edges of the first semiconductor chip 120a. Here, the bulk modulus of the second die adhesive 140 is greater than 1 GPa. The second semiconductor chip 120b is mounted on the first semiconductor chip 120a using the second die adhesive 140. The second wires 110b connect bond pads 124 on the second semiconductor chip 120b with the contact units 104 on the basis frame 102. The sealing portion 130 seals the second semiconductor chip 120b and the second wires 110b on the upper surface of the basis frame 102.

The semiconductor package 100A can be used as a small outline package (SOP), a quad flat package (QFP), and a chip scale package (CSP) as well as a BGA package that uses solder balls 150 as external connection terminals.

The basis frame 102 of the semiconductor package can be a lead frame or a printed circuit board (PCB). In addition, the basis frame 102 can be a substrate used in the BGA package, which is either a flexible substrate including circuit patterns that is made of polyimide or a rigid substrate including circuit patterns that is made of FR-4 resin. Adhesive tapes or an epoxy may be used as the first die adhesive 106. The first and second wires 110a and 110b are ball bonded to the bond pads 122, 124 of the first and second semiconductor chips 120a and 120b and are stitch bonded to the contact units 104 on the basis frame 102. However, the first and second wires 110a and 110b may also be stitch bonded to the bond pads 122, 124 of the first and second semiconductor chips 120a and 120b, respectively, and ball bonded to the contact units 104 on the basis frame 102.

The bulk modulus of the second die adhesive 140 is greater than 1 GPa at a temperature of 0° C., and the second die adhesive 140 is expanded to the edges of the first semiconductor chip 120a to fill the interconnection areas of the first wires 110a. Here, the bulk modulus is the value representing the coefficient of elasticity against tensile force. In addition, the modulus characteristic represents the ratio of tensile force to transformation.

If the second die adhesive was made of the same material as the die adhesive included in the conventional semiconductor package which has a bulk modulus less than 1 GPa, the second die adhesive 140 could not absorb the stress caused by thermal expansion and thermal contraction of the first wires 110a, the second die adhesive 140, and the first and second semiconductor chips 120a and 120b. However, the second die adhesive 140 used in the first embodiment has a bulk modulus greater than 1 GPa, and sufficiently absorbs the stress. Accordingly, the first wires 110a are not removed from the bond pads 122 of the first semiconductor chip 120a when the temperature fluctuates.

It is preferable that the size of the second semiconductor chip 120b is the same as or greater than the size of the first semiconductor chip 120a. The sealing portion 130 can be substituted by a ceramic, an encapsulant, or a metal cap instead of the epoxy mold compound (EMC), which can seal the substrate 102 on which the second semiconductor chip 120b and the second wires 110b are formed. Thus, even if the bond pads 122 on the first semiconductor chip 120a are formed near the center of the first semiconductor chip 120a, the first and second semiconductor chips 120a and 120b can be easily stacked.

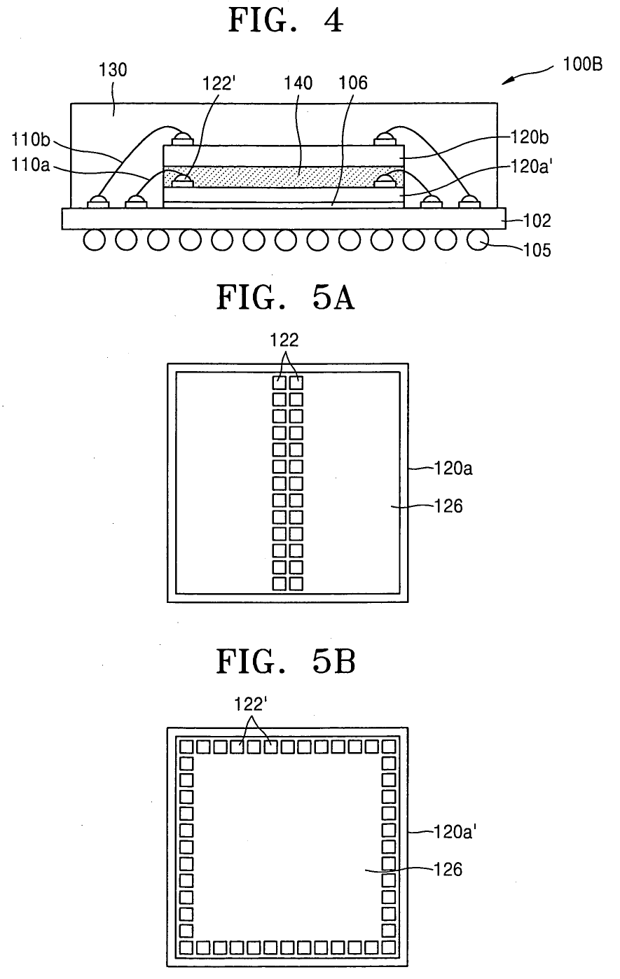

FIG. 4 is a sectional view of a stack type semiconductor package 100B according to a second embodiment of the present invention.

Referring to FIG. 4, the semiconductor package 100B is similar to the semiconductor package 100A, except that bond pads 122′ are formed at the edges of a first semiconductor chip 120a′. Accordingly, further description of the semiconductor package 100B will be omitted.

FIGS. 5A and 5B are plan views of the semiconductor chips used in the semiconductor packages 100A and 100B of FIGS. 3 and 4, respectively.

Referring to FIG. 5A, the semiconductor chip 120a includes the bond pads 122 disposed near the center. In FIG. 5B, the semiconductor chip 120a′ includes the bond pads 122′ near the edges. Both the semiconductor chips 120a and 120a′ include an active region on which circuits are formed.

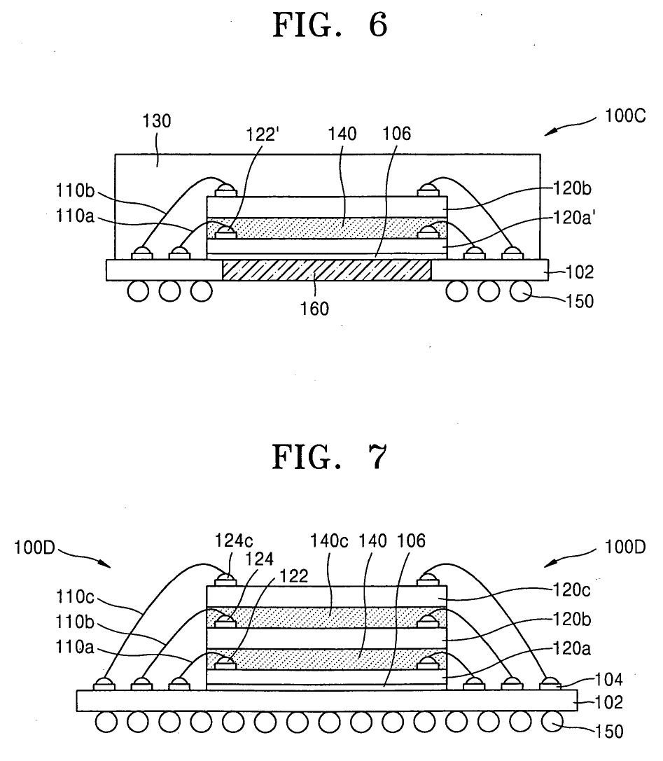

FIG. 6 is a sectional view of a stack type semiconductor package 100C according to a third embodiment of the present invention.

Referring to FIG. 6, the semiconductor package 100C additionally includes a heat sink 160, which is not included in the semiconductor package 100B, below the first die adhesive 106 in order to efficiently extract heat from the first and second semiconductor chips 120a′ and 120b. The material included in, the location of, and the shape of the heat sink 160 can be varied.

FIG. 7 is a sectional view of a stack type semiconductor package 100D according to a fourth embodiment of the present invention.

Referring to FIG. 7, the semiconductor package 100D is identical to the semiconductor package 100B, except that the semiconductor package 100D further includes a third semiconductor chip 120c. The third semiconductor chip 120c is stacked by the same method as the second semiconductor chip 120b. Only three semiconductor chips, 120a,120b, and 120c, are stacked in the semiconductor package 100D, but the number of the semiconductor chips can be greater.

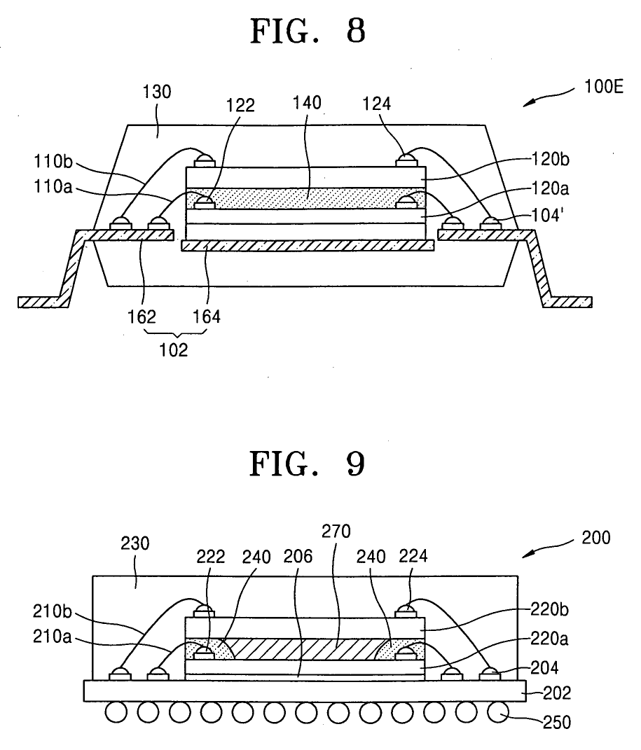

FIG. 8 is a sectional view of a stack type semiconductor package according to a fifth embodiment of the present invention.

Referring to FIG. 8, the semiconductor package 100E is an SOP type semiconductor package. Accordingly, a lead frame 102 that includes a die pad 164 and a lead 162 is used as a basis frame. The remaining structure, including the mounted first and second semiconductor chips 120a and 120b, the first and second wires 110a and 110b, and the sealing of the first and second semiconductor chips 120a and 120b and the first and second wires 110a and 110b using the sealing portion 130 is the same as that in the semiconductor package 100B. The structure of the semiconductor package 100B can be applied to a QFP or a CSP semiconductor package.

FIG. 9 is a sectional view of a stack type semiconductor package 200 according to a sixth embodiment of the present invention.

Referring to FIG. 9, the stack type semiconductor package 200 includes a substrate 202, a first semiconductor chip 220a, first wires 210a, a second die adhesive 240, a third die adhesive 270, a second semiconductor chip 220b, second wires 210b, and a sealing resin 230. Here, the substrate 202 is used as the basis frame of the semiconductor package 200. The first semiconductor chip 220a is mounted on the substrate 202 using a first die adhesive 206. The first wires 210a connect bond pads 222 on the first semiconductor chip 220a with contact units 204 on the substrate 202. The second die adhesive 240 has a bulk modulus greater than 1 GPa and covers the interconnection areas of the first wires 210a on the first semiconductor chips 220a. The third die adhesive 270 completely covers portions of the first semiconductor chip 220a on which the second die adhesive 240 is not coated, with the height of the third die adhesive 270 greater than the height of the first wires 210a. The second semiconductor chip 220b is stacked on the first semiconductor chip 220a using the first and the third die adhesives 240, 270. The second wires 210b connect the bond pads 224 on the second semiconductor chip 220b with the contact units 204 on the substrate 202. The sealing resin 230 seals the second wires 210b and the second semiconductor chip 220b onto the substrate 202.

In the semiconductor package 200, the second die adhesive 240 with the bulk modulus greater than 1 GPa, which prevents the first wires from breaking, is applied to the first wire interconnection areas while not being applied to the entire surface of the first semiconductor chip 220a. Here, the height of the second die adhesive 240 should be such that the interconnection areas of the first wires 210a (i.e., ball bonds) are covered. In addition, a die adhesive with a bulk modulus less than 1 GPa can be used as the third die adhesive 270.

The substrate 202 may be formed by a flexible substrate or a rigid substrate. The bond pads 222 may be formed at the center of the first semiconductor chip 220a or at the edges of the first semiconductor chip 220a, as shown in FIGS. 5A and 5B. It is preferable that the size of the second semiconductor chip 220b is the same as or greater than the size of the first semiconductor chip 220a. The sealing resin 230 can be a ceramic, an encapsulant, or a metal cap, as well as the EMC. The semiconductor package 200 may further include a heat sink, as included in the semiconductor package 100C and may include a third semiconductor chip, as included in the semiconductor package 100D. In addition, the semiconductor package 200 may be part of a SOP, QFP or CSP package as shown in the fifth embodiment of the present invention, instead of the BGA package. It is preferable that the bulk modulus of the second die adhesive 240 be measured at a temperature of 0° C. The stack type semiconductor package 200 may include solder balls 250, which are attached to the lower portion of the substrate 202, as external connection terminals.

In order to determine the effectiveness of the semiconductor package according to the embodiments, the BGA package 100B according to the second embodiment was used as a sample in a temperature cycle test. The conditions of the temperature cycle test were the same as the conditions of the temperature cycle test described in connection with the conventional semiconductor package.

The test performed on the BGA package 100B found that no defects were detected, even when temperature fluctuated between extreme temperatures 150 times, 300 times, 600 times, and 1,000 times.

While the present invention has been particularly shown and described with reference to exemplary embodiments thereof, it will be understood by those of ordinary skill in the art that various changes in form and details may be made therein without departing from the 25 spirit and scope of the present invention as defined by the following claims.

1. A highly reliable stack type semiconductor package comprising:
a basis frame;
a first semiconductor chip that is mounted on the basis frame using a first die adhesive;
first wires, to connect bond pads on the first semiconductor chip with contact units on the basis frame;
a second die adhesive that has a bulk modulus greater than 1 GPa, and is disposed on the first semiconductor chip and covers an entire surface of the first semiconductor chip;
a second semiconductor chip that is mounted on the first semiconductor chip by using the second die adhesive;
second wires, to connect bond pads on the second semiconductor chip to the contact units on the basis frame; and
a sealing portion that seals the structure of the semiconductor package above the basis frame.

2. The stack type semiconductor package of claim 1, wherein the basis frame is one selected from a lead frame and a printed circuit board.

3. The stack type semiconductor package of claim 1, wherein the bond pads on the first semiconductor chip are located near a center of the first semiconductor chip or near edges of the first semiconductor chip.

4. The stack type semiconductor package of claim 1, wherein the bulk modulus is measured at a temperature of 0° C.

5. The stack type semiconductor package of claim 1, wherein a size of the second semiconductor chip is the same as or greater than a size of the first semiconductor chip.

6. The stack type semiconductor package of claim 1, wherein the sealing portion is one selected from an epoxy mold compound (EMC), a ceramic, an encapsulant, and a metal cap.

7. The stack type semiconductor package of claim 1, wherein the type of the stack type semiconductor package is one selected from a small outline package (SOP), a quad flat package (QFP), a ball grid array (BGA) package, and a chip scale package (CSP).

8. The stack type semiconductor package of claim 1, further comprising a third semiconductor chip mounted on the second semiconductor chip while having the same structure as the second semiconductor chip.

9. The stack type semiconductor package of claim 1, further comprising a heat sink, which efficiently extracts heat from the first and second semiconductor chips.

10. The stack type semiconductor package of claim 1, further comprising external connection terminals, which are connected to the basis frame.

11. A stack type semiconductor package having high reliability comprising:
a substrate used as a basis frame of the semiconductor package;
a first semiconductor chip that is mounted on the substrate using a first die adhesive;
first wires to connect bond pads on the first semiconductor chip with contact units on the substrate;
an second die adhesive that has a bulk modulus greater than 1 GPa, and covers first wire interconnection areas on the first semiconductor chip;
a third die adhesive to cover a surface of the first semiconductor chip excluding the first wire interconnection areas, and has a height greater than a height of the first wires;
a second semiconductor chip that is mounted on the first semiconductor chip using the third die adhesive;
second wires to connect bond pads on the second semiconductor chip with the contact units on the substrate; and
a sealing portion to seal the structure of the semiconductor package over the substrate.

12. The stack type semiconductor package of claim 11, wherein the substrate is a flexible substrate formed of polyimide and includes circuit patterns.

13. The stack type semiconductor package of claim 11, wherein the substrate is a rigid substrate formed of FR-4 resin and includes circuit patterns.

14. The stack type semiconductor package of claim 11, wherein the bond pads are located near a center of the first semiconductor chip or the bond pads are located near the edges of the first semiconductor package.

15. The stack type semiconductor package of claim 11, wherein a size of the second semiconductor chip is the same as or greater than a size of the first semiconductor chip.

16. The stack type semiconductor package of claim 11, wherein the sealing portion is one selected from an EMC, a ceramic, an encapsulant, and a metal cap.

17. The stack type semiconductor package of claim 11, further comprising a third semiconductor chip having the same structure as the second semiconductor chip, on the second semiconductor chip on which the second wires are formed.

18. The stack type semiconductor package of claim 11, further comprising a heat sink.

19. The stack type semiconductor package of claim 11, wherein the bulk modulus of the second die adhesive is measured at a temperature of 0° C.

20. The stack type semiconductor package of claim 11, further comprising solder balls which are connected to the bottom surface of the substrate.
